(19) United States
(12) Patent Application Publication
(10) Pub. No.: US 2015/0003141 A1
(43) Pub. Date: Jan. 1, 2015

(54) SEMICONDUCTOR MEMORY DEVICE AND REPAIR METHOD THEREOF

(71) Applicant: Samsung Electronics Co., Ltd., Suwon-si (KR)

(72) Inventors: Jong-Pil SON, Seongnam-si (KR); Chul-Woo PARK, Yongin-si (KR); Young-Soo SOHN, Seoul (KR)

(73) Assignee: Samsung Electronics Co., Ltd., Suwon-si (KR)

(21) Appl. No.: 14/220,275

(22) Filed: Mar. 20, 2014

(30) Foreign Application Priority Data
Jun. 26, 2013 (KR) 10-2013-0073872

(51) Int. Cl. G11C 29/00; G11C 11/407; G11C 17/16

(52) U.S. Cl. CPC G11C 29/70; G11C 17/16; G11C 11/407
USPC 365/96

(57) ABSTRACT

A semiconductor memory device is provided which includes a memory cell group and a fuse cell group including at least one fuse cell to store a failed address corresponding to a defective memory cell in the memory cell group; a spare cell group including a spare memory cell configured to replace the defective memory cell included in the memory cell group; a data sensing/selection circuit configured to read data stored in the memory cell group and the spare cell group in response to an activation of the word line; a fuse sense amplifier configured to read the failed address in response to the activation of the word line; and a repair logic circuit configured to control the data sensing/selection circuit in response to the failed address such that the defective memory cell in the memory cell group is replaced by the spare memory cell.

### CROSS-REFERENCE TO RELATED APPLICATIONS

This application claims priority under 35 U.S.C. §119 to Korean Patent Application No. 10-2013-0073872 filed Jun. 26, 2013, in the Korean Intellectual Property Office, the entire contents of which are hereby incorporated by reference.

### BACKGROUND

This disclosure relates to a semiconductor memory device and a repair method thereof, and more particularly, relates to a semiconductor memory device performing a repair operation using a fuse cell array and a repair method thereof.

A semiconductor memory device is a memory device which is fabricated using semiconductors such as silicon (Si), germanium (Ge), gallium arsenide (GaAs), indium phosphide (InP), and so on. Semiconductor memory devices may be classified into volatile memory devices and nonvolatile memory devices.

The volatile memory devices lose stored contents at power-off. The volatile memory devices include, for example, a static RAM (SRAM), a dynamic RAM (DRAM), a synchronous DRAM (SDRAM), and the like.

The DRAM may include a plurality of memory cells arranged in a matrix form. In high-integration and high-speed semiconductor memory devices, the number of defective cells of the memory cells may increase. There is needed a technique for efficient repairing of defective cells to improve yield of a semiconductor memory device.

### SUMMARY

Embodiments of the disclosure provide a semiconductor memory device which comprises a row decoder; a memory cell group connected to the row decoder through a word line, the memory cell group including a plurality of memory cells; a fuse cell group connected to the row decoder through the word line, the fuse cell group including at least one fuse cell configured to store a failed address corresponding to a defective memory cell in the memory cell group; a spare cell group including a spare memory cell to replace the defective memory cell in the memory cell group; a data sensing/selection circuit configured to read data stored in the memory cell group and the spare cell group in response to an activation of the word line; a fuse sense amplifier configured to read the failed address in response to the activation of the word line; and a repair logic circuit configured to control the data sensing/selection circuit in response to the failed address such that the defective memory cell in the memory cell group is replaced by the spare memory cell.

In exemplary embodiments, the fuse cell includes a nonvolatile memory cell.

In exemplary embodiments, the data sensing/selection circuit comprises a column decoder connected to the memory cell group through a plurality of bit lines, and to the spare cell group through a plurality of spare bit lines, the column decoder configured to replace the defective memory cell with the spare memory cell in response to a matching signal, the repair logic circuit is configured to generate the matching signal based on comparing the failed address with a column address received in the semiconductor memory device.

In exemplary embodiments, the semiconductor memory device further comprises a data line selection circuit connected to the data sensing/selection circuit by a plurality of data lines and a spare data line, wherein the at least one fuse cell is further configured to store data line information of the defective memory cell in the memory cell group, the fuse sense amplifier is configured to read the data line information in response to the activation of the word line, and the repair logic circuit is configured to control the data line selection circuit in response to the data line information such that the defective memory cell in the memory cell group is replaced with the spare memory cell.

In exemplary embodiments, the plurality of data lines are connected to the memory cell group and the spare data line is connected to the spare cell group, and the repair logic circuit is configured to control the data line selection circuit in response to the data line information such that a data line connected to the defective memory cell in the memory cell group is replaced with the spare data line.

In exemplary embodiments, the data line selection circuit comprises a plurality of selection circuits configured to replace the data line connected to the defective memory cell in the memory cell group by the spare data line, each of the plurality of selection circuits includes a multiplexer.

In exemplary embodiments, the repair logic circuit is configured to generate a control code corresponding to the plurality of selection circuits in response to the data line information and the plurality of selection circuits are configured to selectively shift a data line in response to the control code.

In exemplary embodiments, the control code is a thermometer code.

Another aspect of embodiments of the disclosure is directed to provide a semiconductor memory device which comprises a row decoder connected to a first word line and a plurality of sub word lines; a memory cell group connected to the row decoder through the plurality of sub word lines, the memory cell group including a plurality of memory cells; a fuse cell group connected to the row decoder through the first word line, the fuse cell group including at least one fuse cell configured to store a failed address corresponding to a defective memory cell in the memory cell group; a spare cell group including a spare memory cell configured to replace the defective memory cell in the memory cell group, the spare cell group coupled to the plurality of sub word lines; and a data sensing/selection circuit is configured to read data stored in the memory cell group and the spare cell group in response to activations of the plurality of sub word lines and the word line, the failed address stored in the fuse cell group is read in response to the activation of the first word line, and the defective memory cell in the memory cell group is replaced in response to the failed address.

In exemplary embodiments, the at least one fuse cell includes an anti-fuse.

In exemplary embodiments, the row decoder comprises an NWE driver configured to generate a first word line enable signal by decoding a first row address; a PXi driver configured to generate a sub word line enable signal by decoding a second row address different from the first row address; and a word line driver configured to select and activate a part of the plurality of sub word lines in response to the first word line enable signal and the sub word line enable signal, the first word line being activated in response to the first word line enable signal.

In exemplary embodiments, the semiconductor memory device includes a data line selection circuit coupled to the data sensing/selection circuit by a plurality of data lines and a spare data line, wherein the at least one fuse cell is further configured to store data line information of the defective memory cell in the memory cell group, wherein the semiconductor memory device is configured to read the data line information in response to an activation of the first word line, and to replace the defective memory cell in the memory cell group with the spare memory cell in the spare cell group in response to the data line information.

In exemplary embodiments, the fuse cell group is placed between the row decoder and the memory cell group.

Still another aspect of embodiments of the disclosure is directed to provide a repair method of a semiconductor memory device. The repair method comprises storing a failed column address in at least a first fuse cell of the fuse cell array, the failed column address corresponding to one or more defective memory cells of the main cell array; activating a first word line coupled to the at least first fuse cell of the fuse cell array, and activating a second word line coupled to one of the one or more defective memory cells of the main cell array and the at least one spare memory cell of the spare cell array; outputting the failed column address from the fuse cell array; comparing a column address received in the semiconductor memory device with the read failed column address; and replacing the defective memory cell in the main cell array with the spare memory cell in the spare cell array in response to a result from the comparison.

In exemplary embodiments, the outputting the failed column address is performed before the column address is applied to the semiconductor memory device. Alternatively, the reading the failed column address starts before the column address is applied to the semiconductor memory device. Additionally, the outputting the failed column address ends before the column address is applied to the semiconductor memory device.

### BRIEF DESCRIPTION OF THE FIGURES

The above and other objects and features will become apparent from the following description with reference to the following figures, wherein like reference numerals refer to like parts throughout the various figures unless otherwise specified, and wherein

FIG. 1 is a block diagram schematically illustrating a semiconductor memory device according to an embodiment;

FIG. 2 is a detailed block diagram of the semiconductor memory device shown in FIG. 1, according to an embodiment;

FIG. 3 is an exemplary timing diagram for describing a repair operation of the semiconductor memory device shown in FIG. 1, according to an embodiment;

FIG. 4 is a block diagram schematically illustrating a semiconductor memory device according to another embodiment;

FIG. 5 is a detailed block diagram of the semiconductor memory device shown in FIG. 4, according to an embodiment;

FIG. 6 is a block diagram schematically illustrating a row decoder shown in FIG. 5, according to an embodiment;

FIG. 7 is a block diagram schematically illustrating a semiconductor memory device according to still another embodiment;

FIG. 8 is a detailed block diagram of the semiconductor memory device shown in FIG. 7, according to an embodiment;

FIG. 9 is a detailed block diagram of an input/output circuit shown in FIG. 8, according to an embodiment;

FIG. 10 is an exemplary table showing a control code for controlling a data line selection circuit shown in FIGS. 8 and 9, according to an embodiment;

FIG. 11 is a block diagram schematically illustrating a memory system including a semiconductor memory device shown in FIGS. 1, 4 and 7 according to certain embodiments; and

FIG. 12 is a block diagram schematically illustrating a mobile device including a semiconductor memory device according to certain embodiments.

### DETAILED DESCRIPTION OF THE EMBODIMENTS

Embodiments will be described in detail with reference to the accompanying drawings. The inventive concept, however, may be embodied in various different forms, and should not be construed as being limited only to the illustrated embodiments. Accordingly, known processes, elements, and techniques are not described with respect to some of the embodiments of the disclosure. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. Unless indicated otherwise, these terms are only used to distinguish one element, component, region, layer or section from another region, layer or section. Thus, a first element, component, region, layer or section discussed below could be termed a second element, component, region, layer or section without departing from the teachings of the disclosure.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

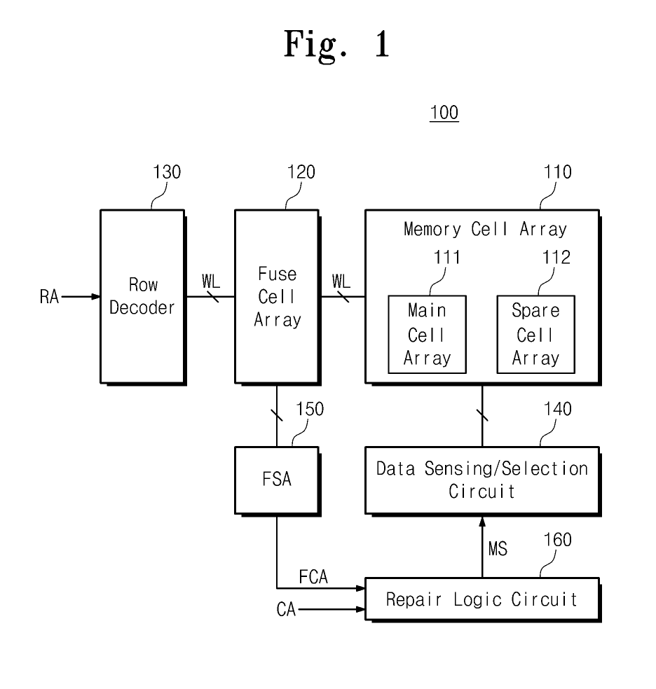

FIG. 1 is a block diagram schematically illustrating semiconductor memory device according to an embodiment.

Referring to FIG. 1, a semiconductor memory device 100, for example, may be implemented by a dynamic random access memory such as a Double Data Rate Synchronous Dynamic Random Access Memory (DDR SDRAM), a Low Power Double Data Rate (LPDDR) SDRAM, a Graphics Double Data Rate (GDDR) SDRAM, a Rambus Dynamic Random Access Memory (RDRAM), etc. However, the disclosure is not limited thereto.

Referring to FIG. 1, the semiconductor memory device 100 includes a memory cell array 110, a fuse cell array 120, a row decoder 130, a data sensing/selection circuit 140, a fuse sense amplifier (marked by ‘FSA’ in FIG. 1) 150, and a repair logic circuit 160.

The semiconductor memory device 100 stores address information of a defective cell of the memory cell array 110 in the fuse cell array 120. Here, a defective cell may be referred to as a defective memory cell, a single bit or a weak cell.

The fuse cell array 120 of the semiconductor memory device 100 shares word lines together with the memory cell array 110. Fuse cells connected to each word line store address information of defective cells among memory cells of the memory cell array 110 connected to the same word line.

Since it does not need an additional register for storing row addresses of defective cells, the semiconductor memory device 100 may implement a repair operation with less area. Also, since the semiconductor memory device 100 may not need loading of any addresses of defective cells into an internal circuit of the semiconductor memory device 100 from a register at booting, it may quickly perform a repair operation. Below, an operation of the semiconductor memory device 100 will be more fully described with reference to accompanying drawings.

The memory cell array 110 includes a plurality of memory cells, which are volatile memory cells. The memory cell array 110 includes a main cell array 111 and a spare cell array 112 for replacing defective cells included in the main cell array 111.

The main cell array 111 includes a plurality of main memory cells for storing data. The main memory cells of the main cell array 111 are connected to a row decoder 130 through the word lines WL.

The spare cell array 112 includes a plurality of spare memory cells for replacing defective cells included in the main cell array 111. In exemplary embodiments, the spare memory cells of the spare cell array 112 are connected to the row decoder 130 through the word lines WL. A connection relation and a structure of the spare cell array 112 are not limited to this disclosure.

The fuse cell array 120 shares the word lines WL together with the memory cell array 110. The fuse cell array 120 may be placed between the row decoder 130 and the memory cell array 110.

The fuse cell array 120 includes a plurality of fuse cells for storing information (hereinafter, referred to as ‘defective cell information’) of defective cells included in the main cell array 111. The defective cell information includes failed column address (FCA) data. The failed column address data may be addresses of defective cells included in the main cell array 111.

Data stored in the fuse cell array 120 is retained although a power supplied thereto is interrupted. For example, the fuse cell array 120 may be implemented using nonvolatile memory cells such as MRAM cells, RRAM cells, etc. Alternatively, the fuse cell array 120 may be implemented using anti-fuses. However, the disclosure is not limited thereto.

Fuse cells connected to each word line of the fuse cell array 120 store defective cell information of main cells of the main cell array 111 connected to the same word line. When a data access operation on main cells connected to a selected word line is performed, data stored in fuse cells connected to the selected word line is read out and used for the data access operation.

The row decoder 130 decodes a row address RA provided from an external device (not shown). The decoded row address is used to select and activate one or more word lines WL. When each of the word lines WL is activated, data is read out from fuse cells connected to the selected word line and from one or more memory cells connected to the selected word line.

The fuse sense amplifier 150 senses and amplifies defective cell information stored in fuse cells of the fuse cell array 120 connected to a selected word line. As described above, the defective cell information may include failed column address (FCA) data. The fuse sense amplifier 150 provides the repair logic circuit 160 with the failed column address (FCA) data read from the fuse cell array 120.

The repair logic circuit 160 compares a column address CA provided from the external device with a failed column address FCA provided from the fuse sense amplifier 150. The repair logic circuit 160 generates a matching signal MS corresponding to the comparison result. The matching signal MS is provided to the data sensing/selection circuit 140.

The data sensing/selection circuit 140 selects one or more bit lines of the memory cell array 110 in response to the matching signal MS provided from the repair logic circuit 160. The matching signal MS indicates a bit line of the main cell array 111 to be inactivated or a spare bit line of the spare cell array 112 to be activated instead of the bit line to be inactivated.

The data sensing/selection circuit 140 senses and amplifies data of a memory cell connected to a selected bit line. The data sensing/selection circuit 140 is configured to output data read from the memory cell to the external device through an input/output circuit. The data sensing/selection circuit 140 is configured to receive write data from the external device through the input/output circuit and to store the received write data in a selected memory cell.

As described above, when a data access operation on memory cells connected to a selected word line, the semiconductor memory device 100 replaces defective cells among memory cells connected to the selected word line with spare memory cells connected to the selected word line and spare bit lines, using data stored in fuse cells connected to the same word line.

Since data of the fuse cells corresponding to memory cells connected to a selected word line are read in response to an activation of the selected word line, the semiconductor memory device 100 performs a repair operation without an additional register for storing row addresses of defective cells. Also, since the semiconductor memory device 100 may not need loading of any addresses of defective cells into an internal circuit of the semiconductor memory device 100 from a register at booting, it may quickly perform a repair operation.

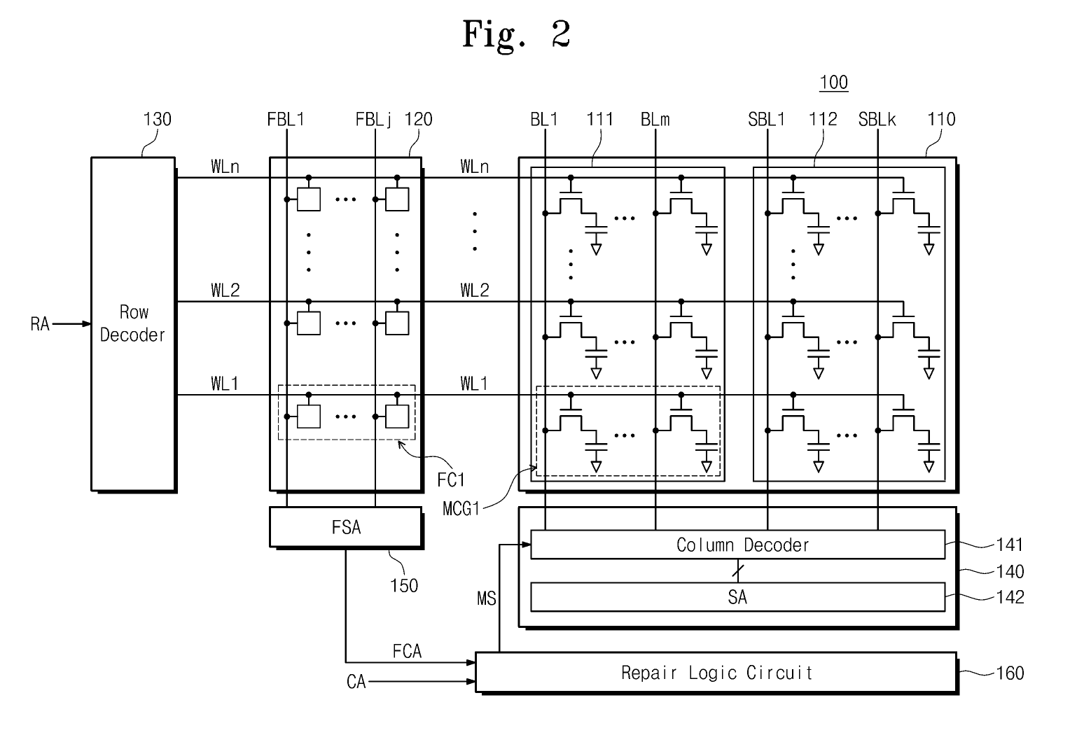

Below, a repair operation of the inventive concept will be more fully described with reference to FIG. 2.

FIG. 2 is a detailed block diagram of the semiconductor memory device shown in FIG. 1, according to an embodiment.

Referring to FIG. 2, a semiconductor memory device 100 shown in FIG. 2 has the same components and operation principle as those of a semiconductor memory device 100 shown in FIG. 1.

A row decoder 130 selects at least one of word lines WL1 to WLn in response to a row decoder RA provided from an external device. The row decoder 130 activates a selected word line. Data stored in fuse cells connected to the selected word line is read in response to an activation of the selected word line.

For example, when a first word line WL1 is selected by the row decoder 130, defective cell information stored in first fuse cells FC1 connected to the first word line WL1 is read.

Defective cell information stored in the first fuse cells FC1 is information associated with defective cells among first main memory cells MCG1 connected to the first word line WL1. Here, the first main memory cells MCG1 are referred to as a first memory cell group. As described above, defective cell information stored in the first fuse cells FC1 includes a failed column address FCA. The failed column address FCA is a column address of defective cells among the first main memory cells MCG1. A fuse sense amplifier 150 provides a repair logic circuit 160 with the read failed column address FCA.

The repair logic circuit 160 compares a column address CA provided from an external device with the failed column address FCA. The repair logic circuit 160 generates a matching signal MS in response to the comparison result. The matching signal MS indicates a bit line of a main cell array 111 to be inactivated and a spare bit line of a spare cell array 112 to be activated instead of the bit line to be inactivated. The repair logic circuit 160 provides the matching signal MS to a data sensing/selection circuit 140.

The data sensing/selection circuit 140 includes a column decoder 141 and a sense amplifier 142. The column decoder 141 selectively activates bit lines connected to the main and spare cell arrays 111 and 112 in response to the matching signal MS. For example, the column decoder 141 inactivates bit lines connected to defective cells included in the main cell array 111. Also, the column decoder 141 activates spare bit lines connected to spare cells for repairing defective cells. The sense amplifier 142 senses and amplifies data stored in selected memory cells connected to the activated bit lines.

As described above, the semiconductor memory device 100 stores information (i.e., failed column addresses) of defective cells connected to each word line in the fuse cell array 120. The fuse cell array 120 shares word lines together with the memory cell array 110. Thus, when the semiconductor memory device 100 performs a data access operation on memory cells connected to a selected word line, it reads a failed column address without additional comparison with a row address and uses the read failed column address for the data access operation.

The semiconductor memory device 100 performs a repair operation without an additional register for storing row addresses of defective cells. Also, since the semiconductor memory device 100 may not need loading of any addresses of defective cells into an internal circuit of the semiconductor memory device 100 from a register at booting, it may quickly perform a repair operation.

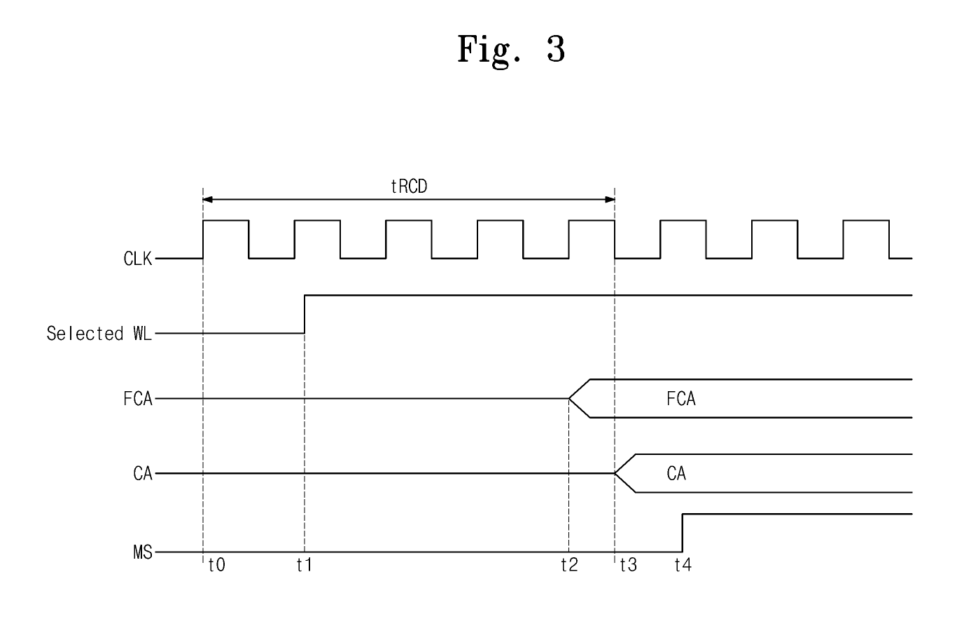

FIG. 3 is an exemplary timing diagram for describing a repair operation of the semiconductor memory device shown in FIG. 1, according to an embodiment.

Referring to FIG. 3, the semiconductor memory device 100 shown in FIG. 1 operates in consideration of a row address to column address delay time tRCD.

At time t0, a row address RA is applied to the semiconductor memory device 100 from an external device.

During a time interval between time t0 and time t1, the input row address is decoded through a row decoder 130 (refer to FIG. 1).

At time t1, one of word lines is selected according to the decoded row address. The row decoder 130 activates the selected word line.

During a time interval between time t1 and time t2, there is performed a read operation on fuse cells connected to the selected word line. At time t2, a read operation on the fuse cells connected to the selected word line ends. A fuse sense amplifier 150 (refer to FIG. 1) senses and amplifies data of a failed column address FCA read from the fuse cells.

At time t3, a column address CA is received in the semiconductor memory device 100 from the external device. A time difference between an input of the row address RA and an input of the column address CA, that is, a time difference between time t0 and time t3 may be defined as a row address to column address delay time tRCD. The row address to column address delay time tRCD is adjusted according to a characteristic of the semiconductor memory device 100.

At time t4, the failed column address FCA read from the fuse cells is compared with the column address CA input from the external device. A matching signal MS is output in response to the comparison result. The failed column address of a memory cell array 110 (refer to FIG. 1) is repaired in response to the matching signal MS.

The failed column address FCA and the column address CA are provided to a repair logic circuit 160 (refer to FIG. 1) to generate the matching signal MS.

In the semiconductor memory device 100, a delay time between an input of a row address and an input of a column address, that is, the row address to column address delay time tRCD has a predetermined value. For example, the failed column address FCA is stored in a fuse cell array 120 (refer to FIG. 1) of the semiconductor memory device 100. Since a data processing speed of the fuse cell array 120 is fast, the semiconductor memory device 100 reads the failed column address FCA before the column address CA is received. The semiconductor memory device 100 utilizes a data processing speed of the fuse cell array 120 to perform a repair operation without an additional delay time for reading the failed column address FCA. For example, since the failed column address FCA is obtained through the fuse sense amplifier 150 within the row address to column address delay time tRCD, the rule on an access speed of the semiconductor memory device 100 may be satisfied.

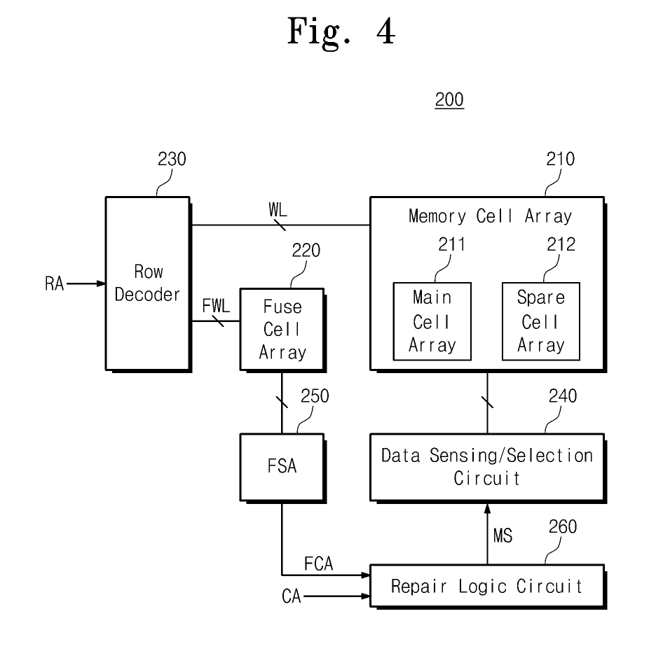

FIG. 4 is a block diagram schematically illustrating a semiconductor memory device according to another embodiment.

Referring to FIG. 4, a semiconductor memory device 200 includes a memory cell array 210, a fuse cell array 220, a row decoder 230, a data sensing/selection circuit 240, a fuse sense amplifier 250, and a repair logic circuit 260.

The memory cell array 210, the row decoder 230, and the data sensing/selection circuit 240 shown in FIG. 4 are substantially the same as those shown in FIG. 1.

The semiconductor memory device 200 stores address information of defective cells in the memory cell array 210 in the fuse cell array 220. In the semiconductor memory device 200, the memory cell array 210 is connected to the row decoder 230 through word lines WL that are divided into a predetermined number of word line groups.

The memory cell array 210 includes a main cell array 211 and a spare cell array 212 for replacing defective cells included in the main cell array 211.

For example, the fuse cell array 220 of the semiconductor memory device 200 is connected to the row decoder 230 through fuse word lines FWL. Each of the fuse word lines FWL corresponds to each of the word line groups, respectively. Fuse cells connected to each fuse word line stores address information of defective cells among memory cells connected to a corresponding word line group of the main cell array 211.

The row decoder 230 selects a part of the word lines WL in response to a row address RA provided from an external device. The row decoder 130 activates a selected word line.

The row decoder 230 activates a fuse word line corresponding to a word line group including the selected word line. Data stored in fuse cells connected to the selected fuse word line is read in response to an activation of the selected fuse word line.

For example, fuse cells connected to a fuse word line store failed column address (FCA) data of defective cells among main cells that are connected to a selected word line of a word line group corresponding to the fuse word line. When a data access operation on memory cells connected to a selected word line is performed, data stored in fuse cells connected to a fuse word line corresponding to a word line group including the selected word line is read and used for the data access operation.

Since fuse cells corresponding to memory cells connected to a selected word line is read in response to an activation of the selected word line, the semiconductor memory device 200 performs a repair operation without an additional register for storing row addresses of defective cells. Also, since the semiconductor memory device 200 may not need loading of any addresses of defective cells into an internal circuit of the semiconductor memory device 200 from a register at booting, it is possible to perform a high-speed repair operation.

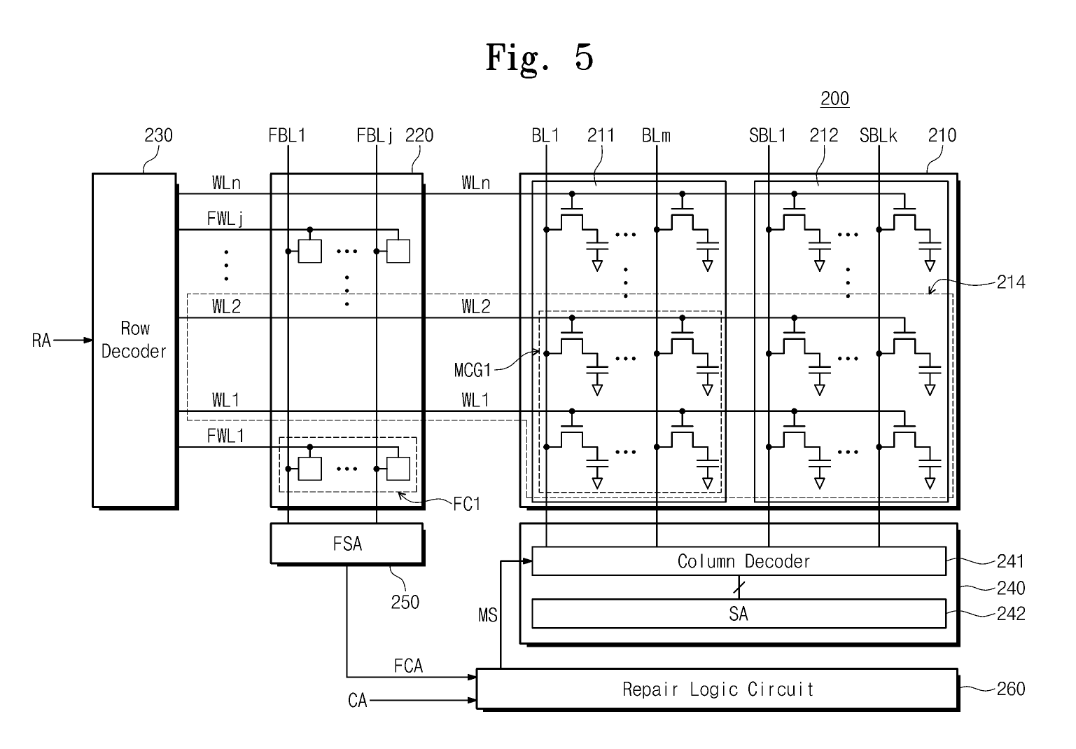

Below, a repair operation of the inventive concept will be more fully described with reference to FIG. 5.

FIG. 5 is a detailed block diagram of the semiconductor memory device shown in FIG. 4, according to an embodiment.

Referring to FIG. 5, a memory cell array 210 is connected to a row decoder 230 through word lines WL1 to WLn. A fuse cell array 220 is connected to the row decoder 230 through fuse word lines FWL1 to FWLj.

The row decoder 230 selects one or more word lines in response to a row address RA provided from an external device. The row decoder 230 activates a selected word line. Also, the row decoder 230 activates a fuse word line corresponding to a word line group including the selected word line.

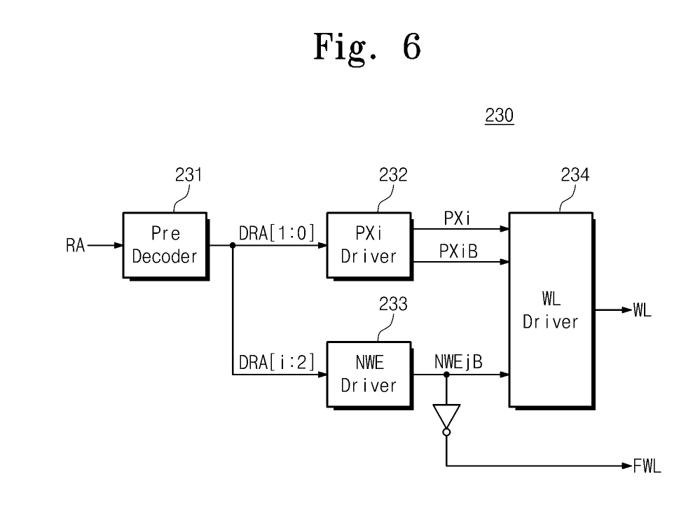

For example, the row decoder 230 activates a fuse word line corresponding to a word line group including a selected word line, using a word line enable signal. This will be more fully described with reference to FIG. 6. Data stored in fuse cells connected to a selected fuse word line is read in response to an activation of the selected fuse word line.

In exemplary embodiments, a first word line WL1 is included in a first word line group 214. When the first word line WL1 is selected by the row decoder 230, there is read defective cell information stored in first fuse cells FC1 that are connected to a first fuse word line FWL1 corresponding to the first word line group 214.

Defective cell information stored in the first fuse cells FC1 is information associated with defective cells included in first main memory cells MCG1 that are connected to a first word line group 214. As described above, defective cell information stored in the first fuse cells FC1 includes a failed column address FCA. The failed column address FCA is a column address of defective cells included in the first main memory cells MCG1. A fuse sense amplifier 250 provides the read failed column address FCA to a repair logic circuit 250.

The repair logic circuit 260 compares the column address CA provided from an external device with the failed column address FCA. The repair logic circuit 260 generates a matching signal MS in response to the comparison result.

The data sensing/selection circuit 240 includes a column decoder 241 and a sense amplifier 242. The column decoder 241 selectively activates bit lines of a main cell array 211 or spare bit lines of a spare cell array 212 in response to the matching signal MS. The sense amplifier 242 senses and amplifies data stored in selected memory cells connected to the activated bit lines.

As described above, the semiconductor memory device 200 stores information (i.e., a failed column address) of defective cells connected to each word line in the fuse cell array 220. A fuse word line FWL of the fuse cell array 220 is activated in response to an activation of a word line included in a word line group corresponding to the fuse word line FWL. Thus, when the semiconductor memory device 200 performs a data access operation on memory cells connected to a selected word line, it reads a failed column address without an additional row address comparison operation and uses the read failed column address for the data access operation.

FIG. 6 is a block diagram schematically illustrating a row decoder shown in FIG. 5, according to an embodiment.

Referring to FIG. 6, a row decoder 230 includes a pre-decoder 231, a PXi driver 232, an NWE driver 233, and a word line driver 234. The row decoder 230 activates a fuse word line corresponding to a word line group including a selected word line, using a main word line enable signal NWEjB on a main word line.

In exemplary embodiments, word lines WL may include a plurality of sub word lines. The sub word lines are divided into a plurality of sub word line groups. Each sub word line group is connected to a main word line.

The pre-decoder 231 decodes a row address RA provided from an external device to generate a decoded row address DRA[1:0]. The decoded row address DRA[1:0] includes a first decoded row address DRA[1:0] and second decoded row address DRA[i:2]. In exemplary embodiments, the first decoded row address DRA[1:0] has a 2-bit length, for example. However, a bit length of the first decoded row address DRA[1:0] may be variable.

The PXi driver 232 generates sub word line enable signals for enabling or disabling a selected sub word line in response to the first decoded row address DRA[1:0].

The NWE driver 233 decodes the second decoded row address DRA[i:2]. The NWE driver 233 generates a main word line enable signal NWEjB for activating a selected main word line.

The word line driver 234 activates a selected sub word line in response to the sub word line enable signals PXi and PXiB and the main word line enable signal NWEjB. Here, a word line corresponding to a sub word line shares the main word line enable signal NWEjB by a 4 or 8. As a result, a row decoder circuit shown in FIG. 6 is generally utilized in a structure where a driving loading is reduced by distributing four or eight word line drivers 234 with respect to a main word line.

According to a circuit structure shown in FIG. 6, a fuse cell array 220 (refer to FIG. 5) is activated together with a selected word line in response to the main word line enable signal NWEjB. Fuse word lines FWL[1:j] (refer to FIG. 5) connected to the fuse cell array 220 are disposed to correspond to main word lines, respectively. Respective fuse word lines are activated in response to an activation of a corresponding main word line.

A semiconductor memory device using the row decoder 230 stores a failed column address of each sub word line in the fuse cell array 220. A fuse word line FWL of the fuse cell array 220 is activated in response to an activation of a sub word line included in a corresponding main word line. Thus, when the semiconductor memory device 200 performs a data access operation on memory cells connected to a selected sub word line, it reads a failed column address without an additional row address comparison operation and uses the read failed column address for the data access operation.

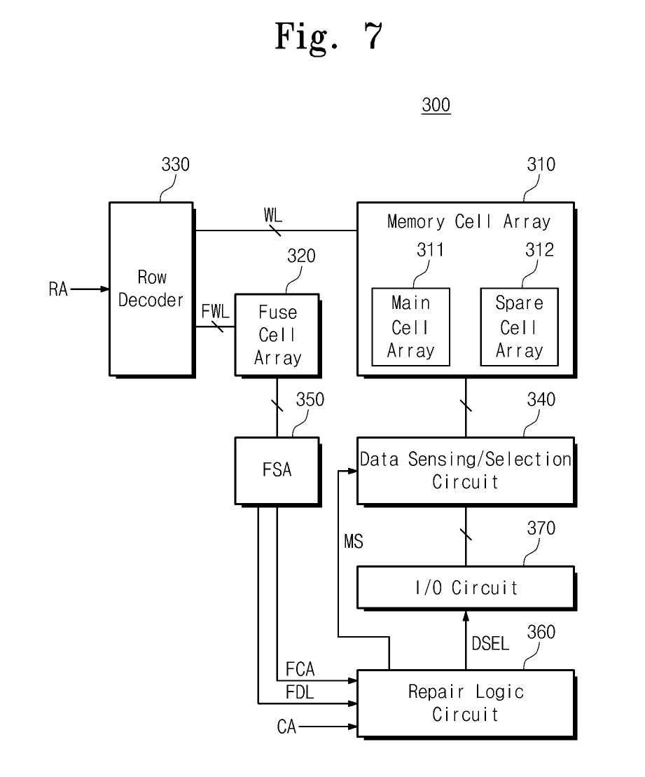

FIG. 7 is a block diagram schematically illustrating a semiconductor memory device according to still another embodiment.

Referring to FIG. 7, a semiconductor memory device 300 includes a memory cell array 310, a fuse cell array 320, a row decoder 330, a data sensing/selection circuit 340, a fuse sense amplifier 350, a repair logic circuit 360, and an input/output circuit 370.

The semiconductor memory device 300 stores address information of defective cells included in the memory cell array 310 in the fuse cell array 320. In addition, the semiconductor memory device 300 stores data line information of defective cells in the memory cell array 310 in the fuse cell array 320.

The semiconductor memory device 300 performs a repair operation on the memory cell array 310 using address information read from the fuse cell array 320. Also, the semiconductor memory device 300 performs a repair operation on the input/output circuit 370 of the semiconductor memory device 300 using data line information read from the fuse cell array 320.

The memory cell array 310 includes a main cell array 311 and a spare cell array 312 for replacing defective cells included in the main cell array 311.

The memory cell array 310 is connected to the row decoder 330 through word lines WL that are divided into a plurality of word line groups. The fuse cell array 320 is connected to the row decoder 330 through fuse word lines FWL. The fuse word lines FWL correspond to the plurality of word line groups, respectively. Fuse cells connected to each fuse word line store address information and data line information of defective cells among memory cells connected to a corresponding word line group.

The row decoder 330 selects one or more word lines WL in response to a row address RA provided from an external device. The row decoder 330 activates a selected word line. The row decoder 330 activates a fuse word line corresponding to a word line group that includes the selected word line. Data stored in fuse cells connected to the selected fuse word line is read in response to an activation of the selected fuse word line.

As described above, fuse word lines of the fuse cell array 320 correspond to a plurality of word line groups, respectively. Fuse cells connected to each fuse word line store address information and data line information of defective cells among memory cells connected to a corresponding word line group.

For example, fuse cells connected to a fuse word line store failed column address (FCA) information of defective cells among main cells connected to a word line group corresponding to the fuse word line and failed data line (FDL) information corresponding thereto.

When a data access operation on memory cells connected to a selected word line is performed, data stored in fuse cells connected to a fuse word line corresponding to a word line group including the selected word line is read and used for the data access operation.

The repair logic circuit 360 performs a repair operation on the memory cell array 310 referring to data read from the fuse cell array 320.

The repair logic circuit 360 compares a column address CA provided from an external device with the failed column address FCA. The repair logic circuit 360 generates a matching signal MS in response to the comparison result. The repair logic circuit 360 provides the matching signal MS to the data sensing/selection circuit 340.

For example, the repair logic circuit 360 generates a data line selection signal DSEL in response to the failed data line (FCL) information. The repair logic circuit 360 provides the data line selection signal SDEL to the input/output circuit 370.

The input/output circuit 370 selects one or more data lines in response to the data line selection signal DSEL. The input/output circuit 370 performs a repair operation on the memory cell array 310 using a data line selection operation.

Since fuse cells corresponding to memory cells connected to a selected word line are read in response to an activation of the selected word line, the semiconductor memory device 300 performs a repair operation without an additional register for storing row addresses of defective cells. Also, the semiconductor memory device 300 may not need loading of any addresses of defective cells into an internal circuit of the semiconductor memory device 300 from a register, so that a high-speed repair operation may be implemented.

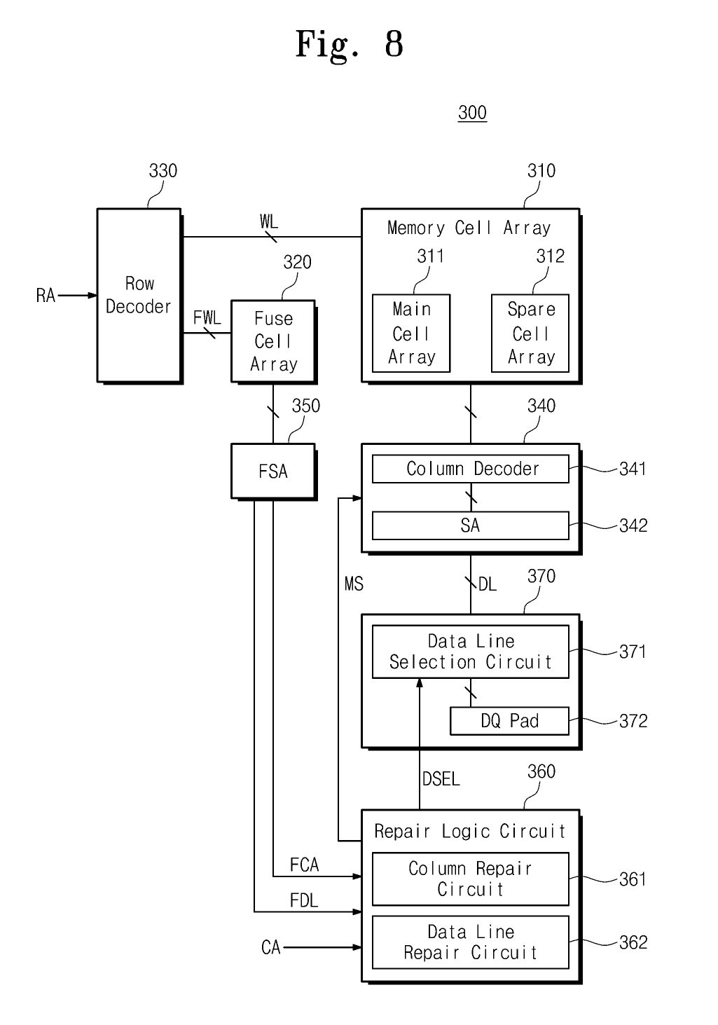

FIG. 8 is a detailed block diagram of the semiconductor memory device shown in FIG. 7, according to one embodiment.

Referring to FIG. 8, a memory cell array 310, a fuse cell array 320, a row decoder 330, and a fuse sense amplifier 350 shown in FIG. 8 are substantially the same as those shown in FIG. 7.

A repair logic circuit 360 performs a repair operation on the memory cell array 310 referring to data read from the fuse cell array 320. The repair logic circuit 360 includes a column repair circuit 361 and a data line repair circuit 362.

The column repair circuit 361 compares a column address CA provided from an external device with a failed column address FCA. The column repair circuit 361 generates a matching signal MS in response to the comparison result. The column repair circuit 361 provides the matching signal MS to a column decoder 341.

A data sensing/selection circuit 340 includes a column decoder 341 and a sense amplifier 342. The column decoder 341 selectively activates bit lines connected to a main cell array 311 or spare bit lines connected to a spare cell array 312 in response to the matching signal MS. A sense amplifier 342 senses and amplifies data stored in selected memory cells connected to the activated bit lines.

For example, the data line repair circuit 362 generates a data line selection signal DSEL referring to failed data line (FDL) information. The data line repair circuit 362 provides the data line selection signal DSEL to the input/output circuit 370.

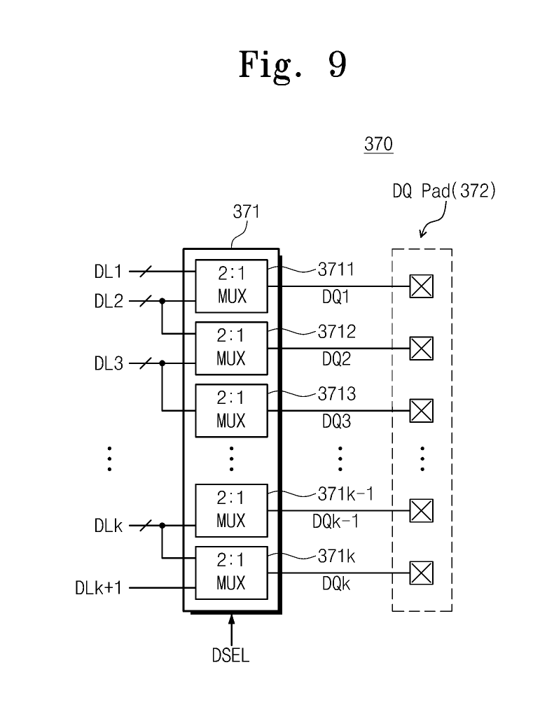

An input/output circuit 370 includes a data line selection circuit 371 and a DQ pad 372. The data line selection circuit 371 selects one or more data lines in response to the data line selection signal DSEL to connect the selected data lines to the DQ pad 372. The data line selection circuit 371 will be more fully described with reference to FIG. 9. The input/output circuit 370 performs a repair operation on the memory cell array 310 using the data line selection circuit 371.

In one embodiment, the input/output circuit 370 is connected to the data sensing/selection circuit 340 by a plurality of data lines DL.

FIG. 9 is a detailed block diagram of an input/output circuit shown in FIG. 8, according to one embodiment.

Referring to FIG. 9, an input/output circuit 370 includes a data line selection circuit 371 and a DQ pad 372.

The data line selection circuit 371 is connected to a plurality of data lines DL1 to DLk+1. The data lines DL1 to DLk+1 may be global data lines connected to a memory cell array 310 (refer to FIG. 8). In one embodiment, the DLk+1 may be a spare data line and coupled to a spare bit line of the spare cell array 312.

The data line selection circuit 371 includes a plurality of selection circuits 3711 to 371k, each of which is formed of a 2:1 multiplexer having first and second inputs and one output. However, the embodiment is not limited thereto.

The selection circuits 3711 to 371k perform selection operations such that there is input and output data corresponding to memory cells except for a defective cell. For example, in the event that a memory cell connected to a first data line DL1 is a defective cell, data of the first data line DL 1 is not transferred through the first data line DL1 connected to the defective cell performing a selection operation on a data line. For example, the data line selection circuit 371 inactivates the first data line DL1 and activates a spare bit line connected to a spare cell in a spare cell array and a data line (e.g., DLk+1) connected to the spare bit line activated. The selection circuits 3711 to 371k perform selection operations by a unit of a data line such that the defective cell is replaced with a spare cell. For example, a selection operation is performed by a unit of a global data line.

As described above, a data line selection operation is performed based on a data line selection signal DSEL provided from a repair logic circuit 360 (refer to FIG. 8). The data line selection signal DSEL is provided to the data line selection circuit 371. Also, a control code for controlling the selection circuits 3711 to 371k may be generated based on the data line selection signal DSEL. Switching operations of the selection circuits 3711 to 371k are controlled by the control code.

Below, a data line selection operation of the data line selection circuit 371 will be described with reference to accompanying drawings. In exemplary embodiments, it is assumed that a data line selection operation is a global data line selection operation.

The first selection circuit 3711 connects one of a first data line DL1 and a second data line DL2 to a DQ input/output pad 372 through a first input/output line DQ1. The second selection circuit 3712 connects one of the second data line DL2 and a third data line DL3 to the DQ input/output pad 372 through a second input/output line DQ2. Likewise, the kth selection circuit 371k connects one of a kth data line DLk and a (k+1)th data line DLk+1 to the DQ input/output pad 372 through a kth input/output line DQk.

In the event that a memory cell connected to a second data line DL2 is a defective cell, the first selection circuit 3711 connects the first data line DL1 to the DQ input/output pad 372. The second selection circuit 3712 connects the third data line DL3 to the DQ input/output pad 372. Likewise, the kth selection circuit 371k connects a (k+1)th data line DLk+1 to the DQ input/output pad 372. For example, the (k+l)th data line DLk+1 may be coupled to a spare bit line of the spare cell array 312 to replace the failed data line DL2 with the (k+l)th data line DLk+1.

With the above-described global data line selection operation, data is input and output through a data line connected to a spare cell array 312, while data on the defective cell connected to the second data line DL2 is not input and output.

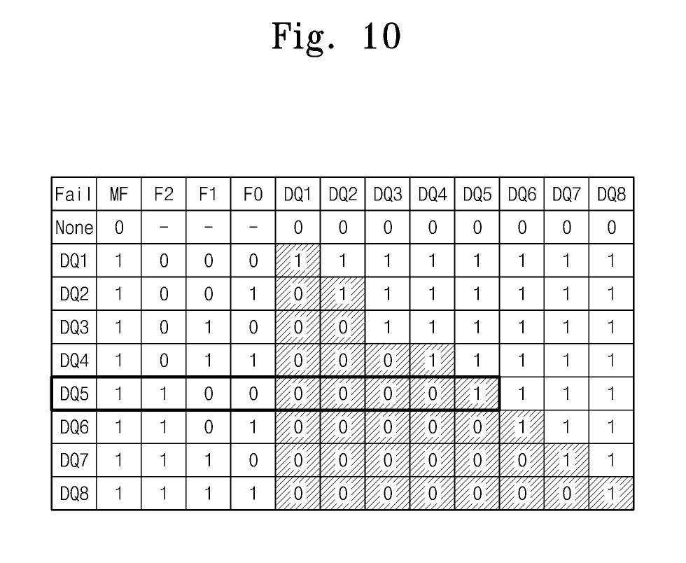

FIG. 10 is an exemplary table showing a control code for controlling a data line selection circuit shown in FIGS. 8 and 9, according to an embodiment.

Referring to FIG. 10, in one embodiment, a control code shown in FIG. 10 may be a thermometer code.

The control code shown in FIG. 10 is stored in a table form. The control code is stored in a storage device (e.g., a nonvolatile storage device) inside or outside a semiconductor memory device 300 (refer to FIG. 8). The control code is loaded onto a repair logic circuit 360 (refer to FIG. 8) when the semiconductor memory device 300 is driven.

Also, in FIG. 10, there is exemplarily shown an embodiment where data is input and output by a unit of eight input/outputs (8 DQs). The control code shown in FIG. 10 is information capable of being stored when the semiconductor memory device 300 has an X8-bit organization. A value of the control code when the semiconductor memory device 300 has another option such as an X4-bit or X16-bit organization is different from that when the semiconductor memory device 300 has the X8-bit organization. For example, in the event that the semiconductor memory device 300 is set have another bandwidth option, bandwidth option information, column address information, input/output unit information, etc. may be variable.

When an address input for an access indicates a cell (i.e., non-defective cell), a matching value is ‘0’. In this case, data is normally output without shifting on a data line (e.g., a global data line).

On the other hand, when an address input for an access indicates a defective cell, a matching value is ‘1’. In this case, a shifting operation on at least one global data line is performed according to the control code shown in FIG. 10.

In exemplary embodiments, if a matching result indicates that a matching value corresponding to any input/output line is ‘1’, a thermometer code stored in the repair logic circuit 360 is output as a control code for controlling selection circuits 3711 to 3718. Each of the selection circuits 3711 to 3718 includes a 2:1 multiplexer having first and second inputs and one output. For example, when a defective cell connected to a fifth data line DL5 is selected, selection circuits corresponding to first to fourth input/output lines DQ1 to DQ4 perform without shifting on a data line (e.g., each of the selection circuits 3711 to 3714 selects a first input). On the other hand, selection circuits corresponding to fifth to eighth input/output lines DQ6 to DQ8 output data with shifting on a data line (e.g., each of the selection circuits 3715 to 3718 selects a second input) such that data of the defective cell is not transferred through the fifth data line DL5.

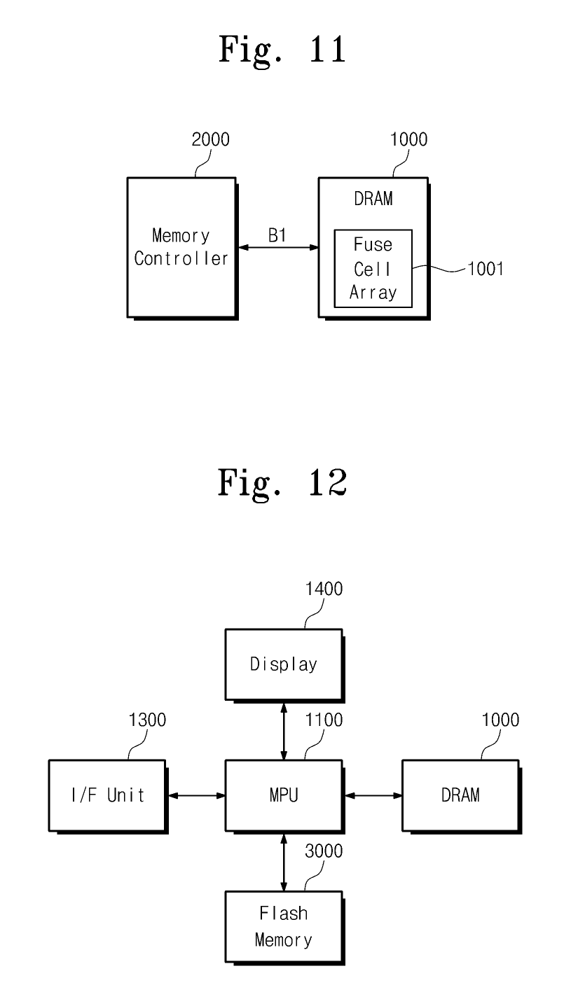

FIG. 11 is a block diagram schematically illustrating a memory system including a semiconductor memory device shown in FIGS. 1, 4 and 7 according to certain embodiments.

Referring to FIG. 11, a memory system includes a memory controller 2000 and a DRAM 1000. The DRAM 1000 is connected to the memory controller 2000 through a system bus B1, and receives data, an address, and a command. The DRAM 1000 provides data read from a memory cell to the memory controller 2000 through the system bus B1.

The memory controller 2000 is connected to a host (not shown) through a predetermined interface.

The DRAM 1000 includes a fuse cell array 1001 that is substantially the same as that shown in FIGS. 1, 4 and 7. In the memory system, since the DRAM 1000 does not need an additional register for storing row addresses of defective cells, it performs a repair operation with a less area. Also, since the DRAM 1000 does not need loading of any addresses of defective cells into an internal circuit of the DRAM 1000 from a register at booting, it may perform a high-speed repair operation. Thus, an area and an operation speed of the memory system including the DRAM 1000 are improved.

FIG. 12 is a block diagram schematically illustrating a mobile device including a semiconductor memory device according to certain embodiments.

Referring to FIG. 12, a mobile device, for example, a notebook computer or a handheld electronic device includes a micro processing unit 1100, an interface unit 1300, a display 1400, a DRAM 1000, and a flash memory 3000.

In some cases, the micro processing unit 1100, the DRAM 1000, and the flash memory 3000 may be integrated in a chip or packaged. For example, the DRAM 1000 and the flash memory 3000 may be embedded in the mobile device.

If the mobile device is a handheld communication device, the interface unit 1300 is connected to a modem for modulating and demodulating data and a transceiver for transmitting and receiving communication data.

The micro processing unit 1100 controls an overall operation of the mobile device according to a predetermined program.

The DRAM 1000 is connected to the micro processing unit 1100, and acts as a buffer memory or a main memory of the micro processing unit 1100. The DRAM 1000 includes a fuse cell array that is substantially the same as that shown in FIGS. 1, 4 and 7. In the mobile device, since the DRAM 1000 does not need an additional register for storing row addresses of defective cells, it may perform a repair operation with a less area. Also, since the DRAM 1000 does not need loading of any addresses of defective cells into an internal circuit of the DRAM 1000 from a register at booting, it may perform a high-speed repair operation. Thus, an area and an operation speed of the mobile device including the DRAM 1000 may be improved.

The flash memory 3000 is a NOR or NAND flash memory.

The display 1400 has a touch screen such as a liquid crystal having a backlight, a liquid crystal having an LED light source, or an element such as OLED. The display 1400 acts as an output device for displaying color images such as characters, numbers, pictures, etc.

The mobile device is described using a mobile communication device. However, the mobile device may act as a smart card by adding or removing components to or from the mobile devices.

The mobile device is connected to an external communication device through a separate interface. The communication device may include a DVD player, a computer, a Set Top Box (STB), a game console, a digital camera, etc.

Although not shown, the mobile device may further comprise an application processor, a camera image processor, a mobile DRAM, etc.

Chips of the mobile device may be packaged using any of various types of packaging technologies. Examples of such packaging technologies include PoP (Package on Package), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP), and the like.

For example, in FIG. 12, there is shown an embodiment where a flash memory is used. Various types of nonvolatile storage may be used instead of the flash memory.

The nonvolatile storage stores data information various formats of data such as text, graphics, software code, etc.

The nonvolatile storage may be EEPROM (Electrically Erasable Programmable Read-Only Memory), STT-MRAM (Spin-Transfer Torque MRAM), CBRAM (Conductive bridging RAM), FeRAM (Ferroelectric RAM), PRAM (Phase change RAM) called OUM (Ovonic Unified Memory), RRAM or ReRAM (Resistive RAM), nanotube RRAM, PoRAM (Polymer RAM), NFGM (Nano Floating Gate Memory), holographic memory, molecular electronics memory device, or insulator resistance change memory.

The disclosure may be modified or changed variously. For example, detailed structures of a fuse cell array, a fuse sense amplifier, and a repair logic circuit may be changed or modified variously according to environment and use. While the disclosure has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A semiconductor memory device, comprising:
a row decoder;
a memory cell group coupled to the row decoder by a word line, the memory cell group including a plurality of memory cells;
a fuse cell group coupled to the row decoder by the word line, the fuse cell group including at least one fuse cell configured to store a failed address corresponding to a defective memory cell in the memory cell group;
a spare cell group including a spare memory cell configured to replace the defective memory cell in the memory cell group;
a data sensing/selection circuit configured to read data stored in the memory cell group and the spare cell group in response to an activation of the word line;
a fuse sense amplifier configured to read the failed address in response to the activation of the word line; and
a repair logic circuit configured to control the data sensing/selection circuit in response to the failed address such that the defective memory cell in the memory cell group is replaced by the spare memory cell.

2. The semiconductor memory device of claim 1, wherein the at least one fuse cell includes a nonvolatile memory cell.

3. The semiconductor memory device of claim 1, wherein the data sensing/selection circuit comprises:
a column decoder coupled to the memory cell group by a plurality of bit lines and to the spare cell group by a plurality of spare bit lines, the column decoder configured to replace the defective memory cell with the spare memory cell in response to a matching signal,
wherein the repair logic circuit is configured to generate the matching signal based on comparing the failed address with a column address received in the semiconductor memory device.

4. The semiconductor memory device of claim 3, wherein the data sensing/selection circuit is configured to select one of the plurality of spare bit lines if the column address is the same as the failed address.

5. The semiconductor memory device of claim 1, further comprising:
a data line selection circuit coupled to the data sensing/selection circuit by a plurality of data lines and a spare data line,
wherein the at least one fuse cell is further configured to store data line information of the defective memory cell in the memory cell group,
wherein the fuse sense amplifier is configured to read the data line information in response to the activation of the word line, and
wherein the repair logic circuit is configured to control the data line selection circuit in response to the data line information such that the defective memory cell in the memory cell group is replaced with the spare memory cell.

6. The semiconductor memory device of claim 5, wherein the plurality of data lines are coupled to the memory cell group and the spare data line is coupled to the spare cell group, and
wherein the repair logic circuit is configured to control the data line selection circuit in response to the data line information such that a data line coupled to the defective memory cell in the memory cell group is replaced with the spare data line.

7. The semiconductor memory device of claim 6, wherein the data line selection circuit comprises:
a plurality of selection circuits configured to replace the data line coupled to the defective memory cell included in the memory cell group by the spare data line, each of the plurality of selection circuits including a multiplexer.

8. The semiconductor memory device of claim 7, wherein the repair logic circuit is configured to generate a control code corresponding to the plurality of selection circuits in response to the data line information, and
wherein the plurality of selection circuits are configured to selectively shift a data line in response to the control code.

9. The semiconductor memory device of claim 8, wherein the control code is a thermometer code.

10. The semiconductor memory device of claim 1, wherein the failed address is a column address of the memory cell group.

11. A semiconductor memory device, comprising:
a row decoder coupled to a first word line and a plurality of sub word lines;
a memory cell group coupled to the row decoder by the plurality of sub word lines, the memory cell group including a plurality of memory cells;
a fuse cell group coupled to the row decoder by the first word line, the fuse cell group including at least one fuse cell configured to store a failed address corresponding to a defective memory cell in the memory cell group;
a spare cell group including a spare memory cell configured to replace the defective memory cell in the memory cell group, the spare cell group coupled to the plurality of sub word lines; and
a data sensing/selection circuit configured to read data stored in the memory cell group and the spare cell group in response to activations of the plurality of sub word lines and the first word line,
wherein the failed address stored in the fuse cell group is read in response to the activation of the first word line, and
wherein the defective memory cell in the memory cell group is replaced in response to the failed address.

12. The semiconductor memory device of claim 11, wherein the at least one fuse cell includes an anti-fuse.

13. The semiconductor memory device of claim 11, wherein the row decoder comprises:
an NWE driver configured to generate a first word line enable signal by decoding a first row address;
a PXi driver configured to generate a sub word line enable signal by decoding a second row address different from the first row address; and
a word line driver configured to select and activate a part of the plurality of sub word lines in response to the first word line enable signal and the sub word line enable signal,
wherein the first word line is activated in response to the first word line enable signal.

14. The semiconductor memory device of claim 11, further comprising:
a data line selection circuit coupled to the data sensing/selection circuit by a plurality of data lines and a spare data line,
wherein the at least one fuse cell is further configured to store data line information of the defective memory cell in the memory cell group,
wherein the semiconductor memory device is configured to read the data line information in response to an activation of the first word line, and to replace the defective memory cell in the memory cell group with the spare memory cell in the spare cell group in response to the data line information.

15. The semiconductor memory device of claim 11, wherein the fuse cell group is placed between the row decoder and the memory cell group.

16. The semiconductor memory device of claim 11, wherein the failed address is a column address of the memory cell group.

17. A method of repairing a defective memory cell in a semiconductor memory device including a main cell array and a spare cell array, the method comprising:
storing a failed column address in at least a first fuse cell of the fuse cell array, the failed column address corresponding to one or more defective memory cells in the main cell array;
activating a first word line coupled to the at least first fuse cell of the fuse cell array, and activating a second word line coupled to one of the one or more defective memory cells in the main cell array and the at least one spare memory cell in the spare cell array;
outputting the failed column address from the fuse cell array;
comparing a column address received in the semiconductor memory device with the failed column address; and
replacing the one or more defective memory cells in the main cell array with the at least one spare memory cell in the spare cell array in response to a result from the comparison.

18. The method of claim 17, wherein the outputting the failed column address is performed before the column address is applied to the semiconductor memory device.

19. The method of claim 17, further comprising:
storing data line information in at least a second fuse cell in the fuse cell array related to the one or more defective memory cells in the main cell array.

20. The method of claim 17, wherein the first word line is the same as the second word line.
